(19) United States
(12) Patent Application Publication
(10) Pub. No.: US 2025/0031545 A1
(43) Pub. Date: Jan. 23, 2025

(54) DISPLAY DEVICE

(71) Applicant: Samsung Display Co., LTD., Yongin-si (KR)

(72) Inventors: JUNGHWAN YI, Yongin-si (KR); SUNG-HOON LIM, Yongin-si (KR); SOODONG KIM, Yongin-si (KR); YUNHA RYU, Yongin-si (KR); KYUMIN KIM, Yongin-si (KR); SEUNGSOK SON, Yongin-si (KR)

(73) Assignee: Samsung Display Co., LTD., Yongin-si (KR)

(21) Appl. No.: 18/746,793

(22) Filed: Jun. 18, 2024

(30) Foreign Application Priority Data
Jul. 19, 2023 (KR) 10-2023-0093840

(51) Int. Cl. H10K 59/38; H10K 59/122

(52) U.S. Cl. CPC H10K 59/38; H10K 59/122

(57) ABSTRACT

A display device includes a via-insulating layer defining a trench including a substantially inclined surface and a substantially flat surface, a light emitting layer on the via-insulating layer and including a first portion parallel to the substantially inclined surface and a second portion disposed parallel to the substantially flat surface, and a color conversion layer on the light emitting layer. A first angle formed between a first imaginary straight line, which connects a point where the first portion and the second portion meet and an edge of the color conversion layer and forms an obtuse angle with the first portion, and a second imaginary straight line, which extends perpendicular to the first portion, is greater than a second angle formed between a travel direction of a light having a greatest luminous intensity among lights emitted from the first portion and the second imaginary straight line.

### CROSS-REFERENCE TO RELATED APPLICATION(S)

This application claims priority to and benefits of Korean Patent Application No. 10-2023-0093840 under 35 U.S.C. § 119, filed on Jul. 19, 2023, in the Korean Intellectual Property Office, the entire contents of which are incorporated herein by reference.

### BACKGROUND

### 1. Technical Field

The disclosure relates generally to a display device. The disclosure relates to a display device that provides visual information.

### 2. Description of the Related Art

With the development of information technology, the importance of a display device, which is a connection medium between a user and information, has been highlighted. For example, the use of display devices such as liquid crystal display (LCD) device, organic light emitting display (OLED) device, plasma display panel (PDP) device, quantum dot display device or the like is increasing.

In order to reduce the light loss of the display device and to display colors with high efficiency, a color conversion layer and a display device including the same have been proposed. Recently, much research is being conducted to improve the light conversion efficiency of the color conversion layer.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device with increased light conversion efficiency.

Embodiments provide a display device in which defects caused by alignment errors are suppressed.

A display device according to an embodiment may include a first substrate including a light emitting area; a via-insulating layer disposed on the first substrate, the via-insulating layer defining a trench including a substantially inclined surface and a substantially flat surface, the trench overlapping the light emitting area; a light emitting layer disposed on the via-insulating layer in the light emitting area, the light emitting layer including a first portion disposed parallel to the substantially inclined surface and a second portion disposed parallel to the substantially flat surface; and a color conversion layer disposed on the light emitting layer and overlapping the light emitting area. A first angle formed between a first imaginary straight line, which connects a point where the first portion and the second portion of the light emitting layer meet and an edge of the color conversion layer and forms an obtuse angle with the first portion, and a second imaginary straight line, which extends perpendicular to the first portion, is greater than a second angle formed between a travel direction of a light having a greatest luminous intensity among lights emitted from the first portion and the second imaginary straight line.

In an embodiment, light having the greatest luminous intensity among the lights emitted from the light emitting layer may be incident on the color conversion layer.

In an embodiment, the trench may have a substantially inverted trapezoid cross-sectional shape.

In an embodiment, the display device may further include a lower electrode disposed between the via-insulating layer and the light emitting layer. The lower electrode may extend into an interior of the trench on the via-insulating layer.

In an embodiment, the lower electrode may include a substantially inclined surface disposed parallel to the substantially inclined surface of the trench and a substantially flat surface disposed parallel to the substantially flat surface of the trench.

In an embodiment, the light emitting area may be disposed along a profile of the lower electrode.

In an embodiment, the light emitting area may include a first light emitting area, a second light emitting area, and a third light emitting area. The trench may overlap each of the first light emitting area, the second light emitting area, and the third light emitting area. The light emitting layer may overlap each of the first light emitting area, the second light emitting area, and the third light emitting area. The color conversion layer may include a first color conversion pattern overlapping the light emitting layer in the first light emitting area, a second color conversion pattern overlapping the light emitting layer in the second light emitting area, and a transmission pattern overlapping the light emitting area in the third light emitting area.

In an embodiment, the display device may further include a pixel defining layer disposed on the via-insulating layer and defining an opening exposing the trench.

In an embodiment, the pixel defining layer may overlap at least a portion of the trench in a plan view.

In an embodiment, the display device may further include a second substrate disposed on the color conversion layer and a filling layer disposed between the first substrate and the second substrate.

A display device according to an embodiment may include a first substrate including a light emitting area; a via-insulating layer disposed on the first substrate, the via-insulating layer defining a trench including a substantially inclined surface and a substantially flat surface, the trench overlapping the light emitting area; a light emitting layer disposed on the via-insulating layer in the light emitting area, the light emitting layer including a first portion disposed parallel to the substantially inclined surface and a second portion disposed parallel to the substantially flat surface, a pixel defining layer disposed on the via-insulating layer, defining an opening exposing the trench, and spaced apart from the trench by a selectable distance in a plan view, and a color conversion layer disposed on the light emitting layer and overlapping the light emitting area. A first angle formed between a first imaginary straight line, which connects a point where the first portion and the second portion of the light emitting layer meet and an edge of the color conversion layer and forms an obtuse angle with the first portion, and a second imaginary straight line, which extends perpendicular to the first portion, is greater than a second angle formed between a travel direction of a light having a greatest luminous intensity among lights emitted from the first portion and the second imaginary straight line.

In an embodiment, a separation distance between the pixel defining layer and the trench may be about 6.6 micrometers or less in the plan view.

In an embodiment, the light emitting layer may further include a third portion disposed on the via-insulating layer, extending from the first portion, and contacting the pixel defining layer.

In an embodiment, the light having a greatest luminous intensity among the lights emitted from the light emitting layer may be incident on the color conversion layer.

In an embodiment, the trench may have a substantially inverted trapezoid cross-sectional shape.

In an embodiment, the display device may further include a lower electrode disposed between the via-insulating layer and the light emitting layer. The lower electrode may extend into an interior of the trench on the via-insulating layer.

In an embodiment, the lower electrode may include a substantially inclined surface disposed parallel to the substantially inclined surface of the trench and a substantially flat surface disposed parallel to the substantially flat surface of the trench.

In an embodiment, the light emitting layer may be disposed along a profile of the lower electrode.

In an embodiment, the light emitting area may include a first light emitting area, a second light emitting area, and a third light emitting area. The trench may overlap each of the first light emitting area, the second light emitting area, and the third light emitting area. The light emitting layer may overlap each of the first light emitting area, the second light emitting area, and the third light emitting area. The color conversion layer may include a first color conversion pattern overlapping the light emitting layer in the first light emitting area, a second color conversion pattern overlapping the light emitting layer in the second light emitting area, and a transmission pattern overlapping the light emitting area in the third light emitting area.

In an embodiment, the display device may further include a second substrate disposed on the color conversion layer and a filling layer disposed between the first substrate and the second substrate.

A display device according to an embodiment may include a via-insulating layer disposed on a first substrate, the via-insulating layer defining a trench which may include substantially inclined surface and a substantially flat surface and overlaps a light emitting area; a light emitting layer disposed on the via-insulating layer in the light emitting area, the light emitting layer including a first portion disposed parallel to the substantially inclined surface and a second portion disposed parallel to the substantially flat surface; and a color conversion layer disposed on the light emitting layer and overlapping the light emitting area. In this case, a first angle formed between a first imaginary straight line, which connects a point where the first portion and the second portion meet and an edge of the color conversion layer and forms an obtuse angle with the first portion, and a second imaginary straight line, which extends perpendicular to the first portion, is greater than a second angle formed between a travel direction of a light having a greatest luminous intensity among lights emitted from the first portion and the second imaginary straight line.

Accordingly, among the lights emitted from the light emitting layer, lights having relatively large luminous intensity may be incident on the color conversion layer. As a result, the light conversion efficiency of the color conversion layer may increase.

A display device according to an embodiment may further include a pixel defining layer disposed on the via-insulating layer and spaced apart from the trench by a selectable distance in a plan view.

Accordingly, defects caused by alignment errors that occur during the manufacturing process of the display device may be suppressed.

### BRIEF DESCRIPTION OF THE DRAWINGS

Illustrative, non-limiting embodiments will be more clearly understood from the following detailed description in conjunction with the accompanying drawings in which:

FIG. 1 is a schematic plan view illustrating a display device according to an embodiment.

FIG. 2 is a schematic cross-sectional view taken along line I-I′ of FIG. 1.

FIG. 3 is a schematic cross-sectional view illustrating a color conversion layer included in the display device of FIG. 2.

FIG. 4 is a view illustrating a relationship between angle and luminous intensity of light.

FIG. 5 is a schematic cross-sectional view illustrating a direction in which light emitted from a light emitting layer travels in a display device according to a comparative example.

FIG. 6 is a schematic cross-sectional view illustrating a direction in which light emitted from a light emitting layer travels in the display device of FIG. 2.

FIG. 7 is a schematic cross-sectional view for explaining a first angle.

FIG. 8 is a view for explaining a second angle.

FIG. 9 is a schematic cross-sectional view illustrating a display device according to an embodiment.

FIG. 10 is an enlarged schematic cross-sectional view of area ‘A’ of FIG. 9.

### DETAILED DESCRIPTION OF THE EMBODIMENTS

Hereinafter, embodiments will be described in detail with reference to the accompanying drawings. The same reference numerals are used for the same components in the drawings, and redundant descriptions of the same components will be omitted.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

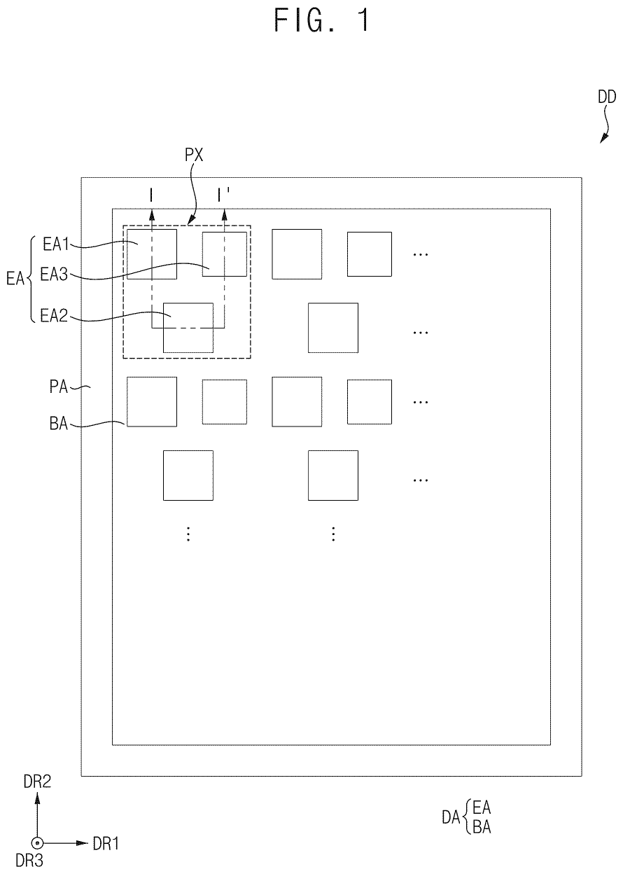

FIG. 1 is a schematic plan view illustrating a display device according to an embodiment.

In this specification, a plane may be defined by a first direction DR1 and a second direction DR2 intersecting the first direction DR1. For example, the first direction DR1 and the second direction DR2 may be perpendicular to each other. A direction normal to the plane, for example, a thickness direction of a display device DD may be a third direction DR3. In other words, the third direction DR3 may be perpendicular to each of the first direction DR1 and the second direction DR2.

Referring to FIG. 1, a display device DD according to an embodiment may include a display area DA and a peripheral area PA. The display area DA may be defined as an area that displays an image. The peripheral area PA may be defined as an area that does not display the image. The peripheral area PA may be positioned around the display area DA. For example, the peripheral area PA may entirely surround or may be adjacent to the display area DA.

Pixels PX for generating the image may be disposed in the display area DA. Each of the pixels PX may include a first sub-pixel, a second sub-pixel, and a third sub-pixel.

The display area DA may include light emitting areas EA and a light blocking area BA. Each of the light emitting areas EA may include a first light emitting area EA1, a second light emitting area EA2, and a third light emitting area EA3. In this case, the first sub-pixel may overlap the first light emitting area EA1, the second sub-pixel may overlap the second light emitting area EA2, and the third sub-pixel may overlap the third light emitting area EA3.

Each of the first to third light emitting areas EA1, EA2, and EA3 may be an area where light emitted from a light emitting element is emitted to an outside of the display device DD. For example, the first light emitting area EA1 may emit a first light, the second light emitting area EA2 may emit a second light, and the third light emitting area EA3 may emit a third light. In an embodiment, the first light may be red light, the second light may be green light, and the third light may be blue light. However, the disclosure is not limited thereto. For example, the first to third light emitting areas EA1, EA2, and EA3 may be combined to emit yellow, cyan, and magenta lights.

In a plan view, each of the first to third light emitting areas EA1, EA2, and EA3 may be repeatedly arranged or disposed along a row direction and a column direction. In other words, each of the first to third light emitting areas EA1, EA2, and EA3 may be repeatedly arranged or disposed along the first direction DR1 and the second direction DR2. For example, the first light emitting area EA1 and the third light emitting area EA3 may be alternately arranged or disposed along the first direction DR1 in an odd row (for example, a first row) of the display area DA. The second light emitting area EA2 may be repeatedly arranged or disposed along the first direction DR1 in an even row (for example, a second row) adjacent to the odd row of the display area DA.

Areas of the first to third light emitting areas EA1, EA2, and EA3 may be different from each other. In an embodiment, the area of the first light emitting area EA1 that emits red light may be larger than the area of the second light emitting area EA2 that emits green light and the area of the third light emitting area EA3 that emits blue light. In this case, the area of the second light emitting area EA2 may be larger than the area of the third light emitting area EA3. However, the disclosure is not limited thereto. For example, the area of the second light emitting area EA2 that emits green light may be larger than the area of the first light emitting area EA1 that emits red light and the area of the third light emitting area EA3 that emits blue light. In this case, the area of the first light emitting area EA1 may be larger than the area of the third light emitting area EA3.

Each of the first to third light emitting areas EA1, EA2, and EA3 may have one of a triangular planar shape, a square planar shape, a circular planar shape, a track-shaped planar shape, an elliptical planar shape, etc. In an embodiment, each of the first to third light emitting areas EA1, EA2, and EA3 may have a rectangular planar shape.

The light blocking area BA may be positioned between the first to third light emitting areas EA1, EA2, and EA3. For example, the light blocking area BA may surround the first to third light emitting areas EA1, EA2, and EA3 in a plan view. The light blocking area BA may be defined as an area that does not emit light.

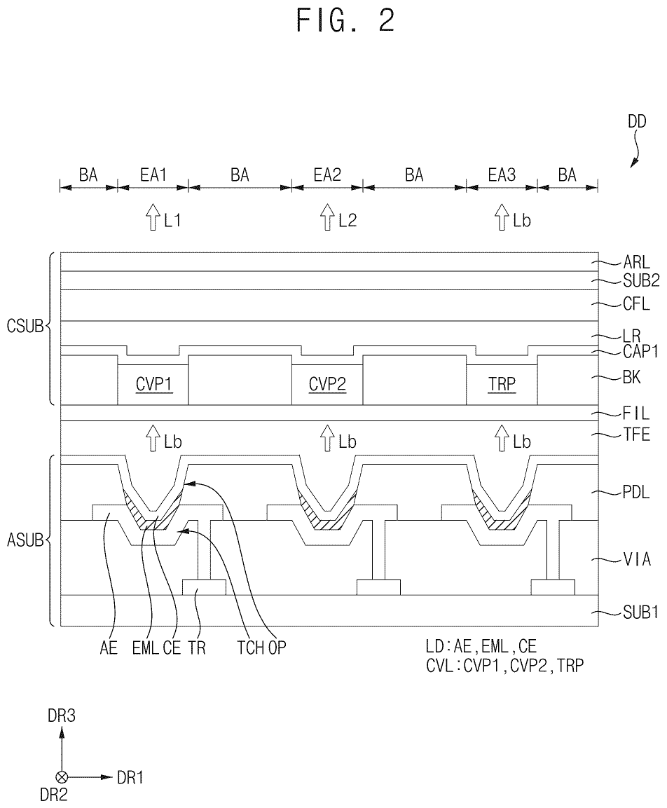

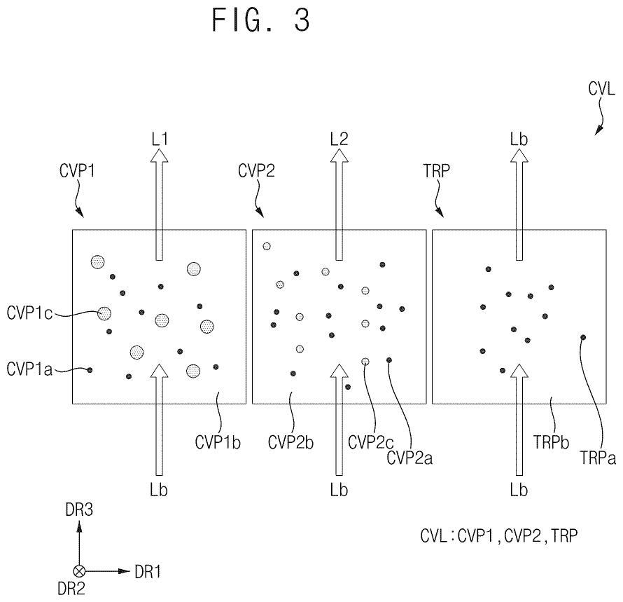

FIG. 2 is a schematic cross-sectional view taken along line I-I′ of FIG. 1. FIG. 3 is a schematic cross-sectional view illustrating a color conversion layer included in the display device of FIG. 2.

Referring to FIGS. 2 and 3, the display device DD according to an embodiment may include an array substrate ASUB, a color conversion substrate CSUB, and a filling layer FIL disposed between the array substrate ASUB and the color conversion substrate CSUB.

The array substrate ASUB may include a first substrate SUB1, a driving element TR, an insulating structure, a via-insulating layer VIA, a light emitting element LD, a pixel defining layer PDL, and an encapsulation layer TFE. In this case, the light emitting element LD may include a lower electrode AE, a light emitting layer EML, and an upper electrode CE.

The color conversion substrate CSUB may include an anti-reflection layer ARL, a second substrate SUB2, a color filter layer CFL, a low refractive layer LR, a first capping layer CAP1, a bank layer BK, a color conversion layer CVL, and a second capping layer. In this case, the color conversion layer CVL may include a first color conversion pattern CVP1, a second color conversion pattern CVP2, and a transmission pattern TRP.

The first substrate SUB1 may include a transparent material or an opaque material. The first substrate SUB1 may be formed of a transparent resin substrate. A polyimide substrate may be an example of the transparent resin substrate. In this case, the polyimide substrate may include a first organic layer, a first barrier layer, a second organic layer, etc. By way of example, the first substrate SUB1 may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

The driving element TR may be disposed on the first substrate SUB1. In an embodiment, the driving element TR may include a thin film transistor. For example, the driving element TR may include amorphous silicon, polycrystalline silicon, or a metal oxide semiconductor.

The metal oxide semiconductor may include a binary compound (ABₓ), a ternary compound (ABₓC_{y}), a quaternary compound (ABₓC_{y}D_{z}), or the like including indium (In), zinc (Zn), gallium (Ga), tin (Sn), titanium (Ti), aluminum (Al), hafnium (Hf), zirconium (Zr), magnesium (Mg), etc. For example, the metal oxide semiconductor may include zinc oxide (ZnO), indium tin oxide (ITO), indium zinc tin oxide (IZTO), indium gallium zinc oxide (IGZO), etc. These may be used alone or in combination with each other.

The insulating structure may be disposed on the first substrate SUB1. The insulating structure may cover the driving element TR. The insulating structure may include an inorganic insulating layer and/or an organic insulating layer. For example, the inorganic insulating layer may include silicon oxide (SiOₓ), silicon nitride (SiNₓ), silicon carbide (SiCₓ), silicon oxynitride (SiOₓN_{y}), silicon oxy carbide (SiOₓC_{y}), etc. The organic insulating layer may include photoresist, polyacryl-based resin, polyimide-based resin, polyamide-based resin, siloxane-based resin, acryl-based resin, epoxy-based resin, etc. These may be used alone or in combination with each other.

The via-insulating layer VIA may be disposed on the insulating structure. For example, the via-insulating layer VIA may be disposed with a relatively thick thickness. A contact hole may be defined in the via-insulating layer VIA. The contact hole may expose a portion of the driving element TR. The via-insulating layer VIA may include an organic insulating material or an inorganic insulating material. In an embodiment, the via-insulating layer VIA may include an organic insulating material. For example, the via-insulating layer VIA may include photoresist, polyacryl-based resin, polyimide-based resin, polyamide-based resin, siloxane-based resin, acryl-based resin, epoxy-based resin, etc. These may be used alone or in combination with each other.

In an embodiment, the via-insulating layer VIA may define a trench TCH. The trench TCH may refer to a portion where a portion of an upper surface of the via-insulating layer VIA is recessed toward the first substrate SUB1. The trench TCH may overlap each of the first light emitting area EA1, the second light emitting area EA2, and the third light emitting area EA3.

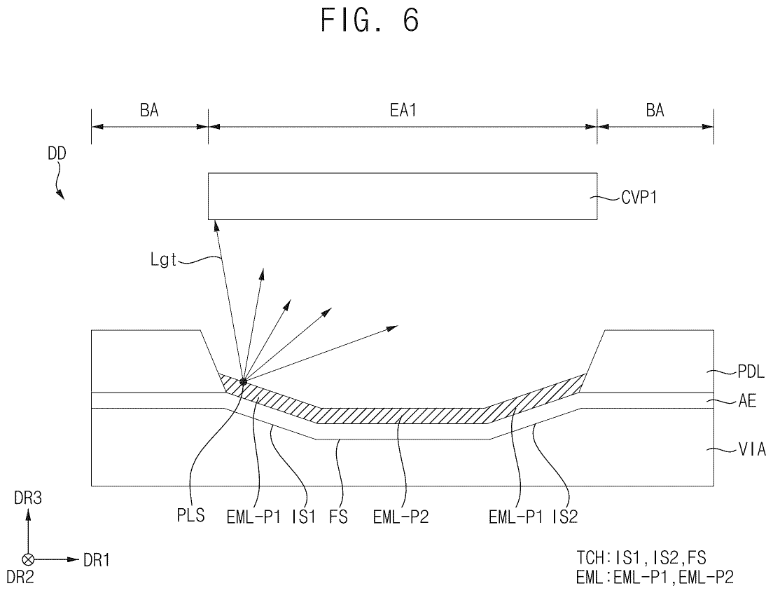

In an embodiment, the trench TCH may have a substantially inverted trapezoid cross-sectional shape. In other words, the trench TCH has a first inclined surface (for example, a first inclined surface IS1 of FIG. 6), a second inclined surface (for example, the second inclined surface IS2 of FIG. 6), and a flat surface (for example a flat surface FS of FIG. 6). In cross section, the first inclined surface may be spaced apart from the second inclined surface with the flat surface interposed therebetween. The first inclined surface may face the second inclined surface. The flat surface may contact each of the first inclined surface and the second inclined surface. However, the disclosure is not limited thereto.

The lower electrode AE may be disposed on the via-insulating layer VIA. In other words, the lower electrode AE may be disposed between the via insulating layer VIA and the light emitting layer EML. The lower electrode AE may overlap each of the first light emitting area EA1, the second light emitting area EA2, and the third light emitting area EA3. The lower electrode AE may be electrically connected to the driving element TR through the contact hole formed in the via-insulating layer VIA.

In an embodiment, the lower electrode AE may extend into an interior of the trench TCH on the via-insulating layer VIA. In other words, the lower electrode AE may be disposed along the profile of the via-insulating layer VIA.

Accordingly, an upper surface of the lower electrode AE may include a first inclined surface, a second inclined surface, a first flat surface, a second flat surface, and a third flat surface. In cross section, the first inclined surface may be spaced apart from the second inclined surface with the first flat surface interposed between. The first inclined surface may face the second inclined surface. The second flat surface may extend from the first inclined surface and may partially overlap the pixel defining layer PDL. The third flat surface may extend from the second inclined surface and may partially overlap the pixel defining layer PDL.

In this case, the first inclined surface, the second inclined surface, and the first flat surface of the lower electrode AE may be disposed parallel to the first inclined surface, the second inclined surface, and the flat surface of the trench TCH, respectively.

For example, the lower electrode AE may include a metal, an alloy, a metal nitride, a conductive metal oxide, a transparent conductive material, etc. Examples of material that may be used as the lower electrode AE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These may be used alone or in combination with each other. For example, the lower electrode AE may serve as an anode electrode.

The pixel defining layer PDL may be disposed on the via-insulating layer VIA and the lower electrode AE in the light blocking area BA. An opening OP exposing the trench TCH may be defined in the pixel defining layer PDL. The pixel defining layer PDL may cover an edge of the lower electrode AE and expose the upper surface of the lower electrode AE.

In an embodiment, the pixel defining layer PDL may overlap at least a portion of the trench TCH in a plan view. For example, one end or an end of the pixel defining layer PDL may extend to a point where the second flat surface of the lower electrode AE and the first inclined surface of the lower electrode AE meet. The other end of the pixel defining layer PDL may extend to a point where the third flat surface of the lower electrode AE and the second inclined surface of the lower electrode AE meet. However, the disclosure is not limited thereto.

The pixel defining layer PDL may include an organic insulating material or an inorganic insulating material. In an embodiment, the pixel defining layer PDL may include an organic insulating material. Examples of the organic insulating material that may be used as the pixel defining layer PDL may include photoresist, polyacryl-based resin, polyimide-based resin, polyamide-based resin, siloxane-based resin, acryl-based resin, epoxy-based resin, etc. These may be used alone or in combination with each other.

The light emitting layer EML may be disposed on the via-insulating layer VIA. As an example, the light emitting layer EML may be disposed on the lower electrode AE. The light emitting layer EML may overlap each of the first light emitting area EA1, the second light emitting area EA2, and the third light emitting area EA3. For example, a hole provided from the lower electrode AE and an electron provided from the upper electrode CE may combine in the light emitting layer EML to form an exciton. As the exciton changes from the excited state to the ground state, the light emitting layer EML may emit light. The light emitting layer EML may emit light having given colors (for example, red, green, and blue). In an embodiment, the light emitting layer EML may emit a blue light Lb.

In an embodiment, the light emitting layer EML may be disposed along the profile of the lower electrode AE. Accordingly, the light emitting layer EML may include a first portion (for example, a first portion EML-P1 of FIG. 6) disposed parallel to each of the first and second inclined surfaces of the lower electrode AE and a second portion (for example, a second portion EML-P2 of FIG. 6) disposed parallel to the first flat surface of the lower electrode AE. For example, the first portion of the light emitting layer EML may be disposed parallel to each of the first and second inclined surfaces of the trench TCH, and the second portion of the light emitting layer EML may be disposed parallel to the flat surface of the trench TCH.

For example, the light emitting layer EML may have a single layer structure including one light emitting layer. By way of example, the light emitting layer EML may have a tandem structure in which light emitting layers may be stacked each other.

The upper electrode CE may be disposed on the light emitting layer EML and the pixel defining layer PDL. The upper electrode CE may be entirely disposed in the first to third light emitting areas EA1, EA2, and EA3 and the light blocking area BA. The upper electrode CE may be disposed along the profiles of the pixel defining layer PDL and the light emitting layer EML. For example, the upper electrode CE may include a metal, an alloy, a metal nitride, a conductive metal oxide, a transparent conductive material, etc. These may be used alone or in combination with each other. For example, the upper electrode CE may serve as a cathode electrode.

Accordingly, the light emitting element LD including the lower electrode AE, the light emitting layer EML, and the upper electrode CE may be disposed on the via-insulating layer VIA. The light emitting element LD may be electrically connected to the driving element TR. In an embodiment, the light emitting element LD may include a blue light emitting element that emits the blue light Lb.

The encapsulation layer TFE may be disposed on the upper electrode CE. The encapsulation layer TFE may prevent impurities, moisture, etc. from penetrating into the light emitting element LD from the outside. The encapsulation layer TFE may include at least one inorganic encapsulation layer and at least one organic encapsulation layer. For example, the inorganic encapsulation layer may include silicon oxide (SiOx), silicon nitride (SiNx), silicon oxynitride (SiOxNy), etc. These may be used alone or in combination with each other. For example, the organic encapsulation layer may include a cured polymer such as polyacrylate.

The second substrate SUB2 may be formed of a transparent resin substrate. For example, the second substrate SUB2 may include an insulating material such as glass or plastic. By way of example, the second substrate SUB2 may include an organic polymer material such as polycarbonate, polyethylene, polypropylene, etc. These may be used alone or in combination with each other.

The anti-reflection layer ARL may be disposed on the second substrate SUB2. External light may enter the display device DD. The external light may be reflected from various electrodes or lines included in the display device DD. The anti-reflection layer ARL may prevent the reflected external light from being recognized to the user.

The anti-reflective layer ARL may include inorganic and/or organic materials. For example, the anti-reflection layer ARL may include acryl-based resin, methacryl-based resin, vinyl-based resin, epoxy-based resin, urethane-based resin, cellulose-based resin, perylene-based resin, silsesquioxane-based resin (for example, polyhedral oligomeric silsesquioxane, POSS), etc. These may be used alone or in combination with each other. The anti-reflection layer ARL may include a thermosetting material or a photocurable material.

The color filter layer CFL may be disposed under or below the second substrate SUB2. The color filter layer CFL may include a black matrix and color filters disposed in a space defined by the black matrix. The black matrix may overlap the light blocking area BA. The color filters may include a first color filter overlapping the first light emitting area EA1, a second color filter overlapping the second light emitting area EA2, and a third color filter overlapping the third light emitting area EA3. For example, the first color filter may be a red color filter, the second color filter may be a green color filter, and the third color filter may be a blue color filter.

The low refractive layer LR may be disposed under or below the color filter layer CFL. The low refractive layer LR may be disposed entirely in the first to third light emitting areas EA1, EA2, and EA3 and the light blocking area BA. The low refractive layer LR may increase the light conversion efficiency of the color conversion layer CVL.

The low refractive layer LR may have a relatively low refractive index. For example, the refractive index of the low refractive layer LR may be lower than a refractive index of the color conversion layer CVL. The low refractive layer LR may include an organic material. For example, the low refractive layer LR may include an organic polymer material including silicon.

The first capping layer CAP1 may be disposed under or below the low refractive layer LR. The first capping layer CAP1 may be entirely disposed in the first to third light emitting areas EA1, EA2, and EA3 and the light blocking area BA. The first capping layer CAP1 may act as a moisture barrier to prevent deterioration of the low refractive layer LR.

The first capping layer CAP1 may include a silicon compound. For example, the first capping layer CAP1 may include silicon oxide (SiOₓ), silicon nitride (SiNₓ), silicon oxynitride (SiOₓN_{y}), etc. These may be used alone or in combination with each other.

The bank layer BK may be disposed under or below the first capping layer CAP1. The bank layer BK may overlap the light blocking area BA. The bank layer BK may surround the color conversion layer CVL. A space that accommodates an ink composition during the process of forming the color conversion layer CVL may be formed in the bank layer BK. For example, the bank layer BK may have a grid shape or a matrix shape in a plan view.

For example, the bank layer BK may include an organic material such as epoxy-based resin, phenol resin, acrylic-based resin, silicone-based resin, etc. These may be used alone or in combination with each other.

The color conversion layer CVL may be disposed under or below the first capping layer CAP1. In case that the array substrate ASUB and the color conversion substrate CSUB are bonded, the color conversion layer CVL may be disposed on the light emitting layer EML. The color conversion layer CVL may overlap the first to third light emitting areas EA1, EA2, EA3. The color conversion layer CVL may convert light emitted from the light emitting layer EML into light having a given wavelength.

The color conversion layer CVL may include the first color conversion pattern CVP1, the second color conversion pattern CVP2, and the transmission pattern TRP. The first color conversion pattern CVP1 may overlap the light emitting layer EML in the first light emitting area EA1. The second color conversion pattern CVP2 may overlap the light emitting layer EML in the second light emitting area EA2. The transmission pattern TRP may overlap the light emitting layer EML in the third light emitting area EA3.

The first color conversion pattern CVP1 may convert the light emitted from the light emitting layer EML (for example, the blue light Lb) into a first color light L1. The second color conversion pattern CVP2 may convert the light emitted from the light emitting layer EML into a second color light L2. The transmission pattern TRP may transmit the light emitted from the light emitting layer EML. In an embodiment, the first color light L1 may be red light, and the second color light L2 may be green light. The transmission pattern TRP may transmit the blue light Lb. However, the disclosure is not limited thereto.

As illustrated in FIG. 3, the first color conversion pattern CVP1 may include first quantum dots CVP1c that are excited by the light emitted from the light emitting layer EML and emit the first color light L1. The first color conversion pattern CVP1 may further include a first photosensitive polymer CVP1b in which first scattering particles CVP1a are dispersed.

The second color conversion pattern CVP2 may include second quantum dots CVP2c that are excited by the light emitted from the light emitting layer EML and emit light the second color light L2. The second color conversion pattern CVP2 may further include a second photosensitive polymer CVP2b in which second scattering particles CVP2a are dispersed.

The transmission pattern TRP may emit the blue light Lb by transmitting the light emitted from the light emitting layer EML. The transmission pattern TRP may include a third photosensitive polymer TRPb in which third scattering particles TRPa are dispersed.

For example, each of the first to third photosensitive polymers CVP1b, CVP2b, and TRPb may include an organic material having light transparency, such as silicone-based resin or epoxy-based resin. The first to third scattering particles CVP1a, CVP2a, and TRPa may scatter and emit the light emitted from the light emitting layer EML. The first to third scattering particles CVP1a, CVP2a, and TRPa may include the same material as each other.

Accordingly, the first light emitting area EA1 may emit the first color light L1, the second light emitting area EA2 may emit the second color light L2, and the third light emitting area EA3 may emit the blue light Lb.

The second capping layer may be disposed under or below the bank layer BK and the color conversion layer CVL. The second capping layer may entirely cover the bank layer BK and the color conversion layer CVL. For example, the second capping layer may include a silicon compound.

The filling layer FIL may be disposed between the first substrate SUB1 and the second substrate SUB2. In other words, the filling layer FIL may be disposed between the array substrate ASUB and the color conversion substrate CSUB. The filling layer FIL may fill between the array substrate ASUB and the color conversion substrate CSUB. The filling layer FIL may include an organic material having light transparency.

In FIG. 2, the display device DD is described as having a structure including two substrates (for example, the first substrate SUB1 and the second substrate SUB2), but the disclosure is not limited thereto. For example, the display device DD may have a structure including one substrate.

Although the display device DD of the disclosure is described by limiting the organic light emitting display (OLED) device, the configuration of the disclosure is not limited thereto. In other embodiments, the display device DD may include a liquid crystal display (LCD) device, a field emission display (FED) device, a plasma display panel (PDP) device, an electrophoretic image display (EPD) device, an inorganic light emitting display (ILED) device, or a quantum dot display device.

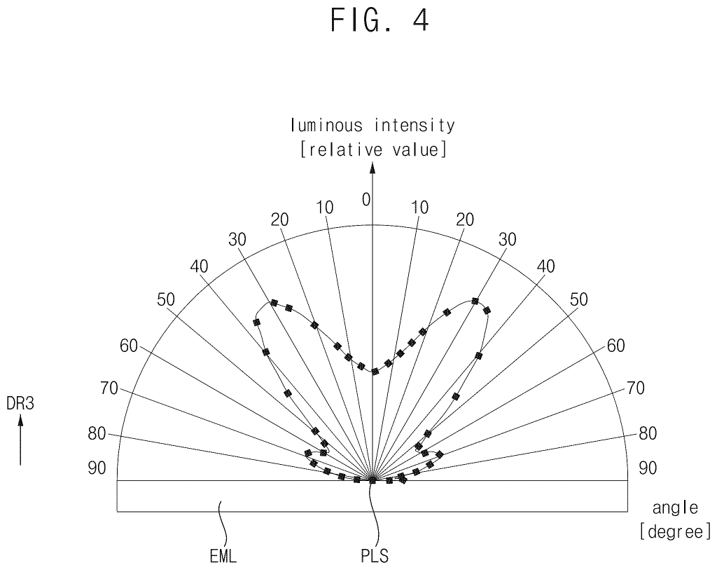

FIG. 4 is a view illustrating a relationship between angle and luminous intensity of light.

Referring to FIG. 4, a horizontal axis may correspond to a surface of the light emitting layer EML in cross-section, and a vertical axis may correspond to a straight line perpendicular to the light emitting layer EML (for example, a straight line parallel to the third direction DR3) in cross-section. The vertical axis may correspond to the luminous intensity of light emitted from the light emitting layer EML. The light emitting layer EML may include a point light source PLS. A point where the horizontal axis and the vertical axis meet may correspond to the point light source PLS. The point light source PLS may emit lights spread out. In other words, the point light source PLS may emit lights at various angles.

As an example, FIG. 4 illustrates the relationship between an angle formed by the straight line perpendicular to the light emitting layer EML in cross-section and a travel direction of the light emitted from the point light source PLS and the luminous intensity of the light. In this case, a luminous intensity of the light in case that the angle is about 30 degrees may be greater than a luminous intensity of the light in case that the angle is about 20 degrees. A luminous intensity of the light in case that the angle is in a range of about 30 degrees to about 40 degrees may be greater than a luminous intensity of the light in case that the angle is in a range of about 0 degrees to about 10 degrees. However, the disclosure is not limited thereto. The relationship between the angle and the luminous intensity of the light may vary depending on a material of the light emitting layer EML and a thickness of the light emitting layer EML.

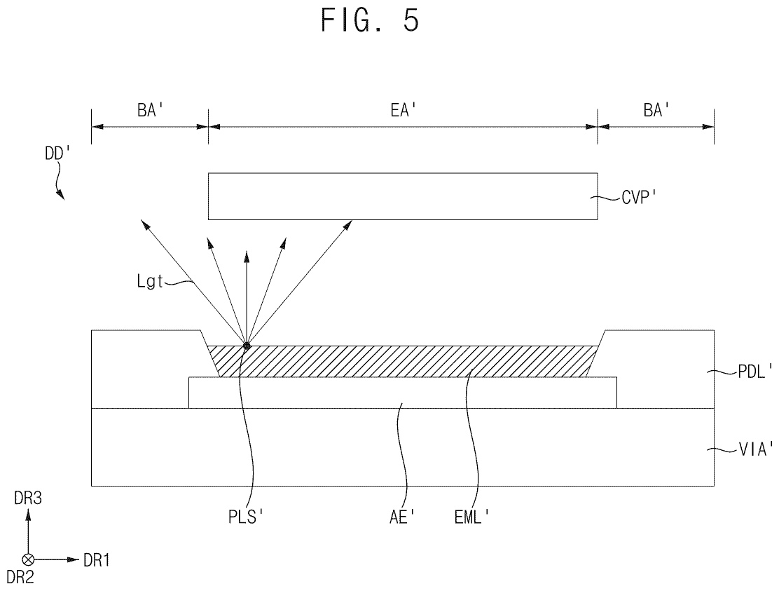

FIG. 5 is a schematic cross-sectional view illustrating a direction in which light emitted from a light emitting layer travels in a display device according to a comparative example.

Referring to FIG. 5, a display device DD′ according to a comparative example may include a via-insulating layer VIA′, a lower electrode AE′, a light emitting layer EML′, a pixel defining layer PDL′, and a color conversion pattern CVP′. In this case, the light emitting layer EML′ may include a point light source PLS′. The display device DD′ may be substantially the same as the display device DD described with reference to FIG. 2, except that each of the via-insulating layer VIA′, the lower electrode AE′, and the light emitting layer EML′ has a flat upper surface.

The via-insulating layer VIA′ may have the flat upper surface. In other words, the via-insulating layer VIA′ may not define the trench (for example, the trench TCH of FIG. 2).

The lower electrode AE′ may be disposed on the via-insulating layer VIA′. The lower electrode AE′ may overlap a light emitting area EA′. The lower electrode AE′ may have the flat upper surface. In other words, the upper surface of the lower electrode AE′ may not include an inclined surface.

The pixel defining layer PDL′ may be disposed on the via-insulating layer VIA′ and the lower electrode AE′ in a light blocking area BA′. The pixel defining layer PDL′ may cover an edge of the lower electrode AE′. An opening that exposes the upper surface of the lower electrode AE′ may be defined.

The light emitting layer EML′ may be disposed on the lower electrode AE′. The light emitting layer EML′ may overlap the light emitting area EA′. The light emitting layer EML′ may include the flat upper surface. In other words, the upper surface of the light emitting layer EML′ may not include an inclined surface.

The color conversion pattern CVP′ may be disposed on the light emitting layer EML′. The color conversion pattern CVP′ may overlap the light emitting layer EML′ in the light emitting area EA′. The color conversion pattern CVP′ may convert the light emitted from the light emitting layer EML′ into a first color light.

The point light source PLS′ included in the light emitting layer EML′ may emit lights. For example, the point light source PLS′ may emit lights at various angles. In FIG. 5, the light emitted from the point light source PLS′ is represented by an arrow. A length of the arrow may correspond to the luminous intensity of the light. In other words, the greater the length of the arrow, the greater the luminous intensity of the light.

Some of the lights emitted from the point light source PLS′ positioned in an area adjacent to the pixel defining layer PDL (for example, an edge of the light emitting layer EML′) may not be incident on the color conversion pattern CVP′. In other words, since the point light source PLS′ emits lights at various angles, some of the lights may not be incident on the color conversion pattern CVP′. For example, a light Lgt having the greatest luminous intensity among the lights may not be incident on the color conversion pattern CVP′. Accordingly, the light conversion efficiency of the color conversion pattern CVP′ included in the display device DD′ may be relatively low.

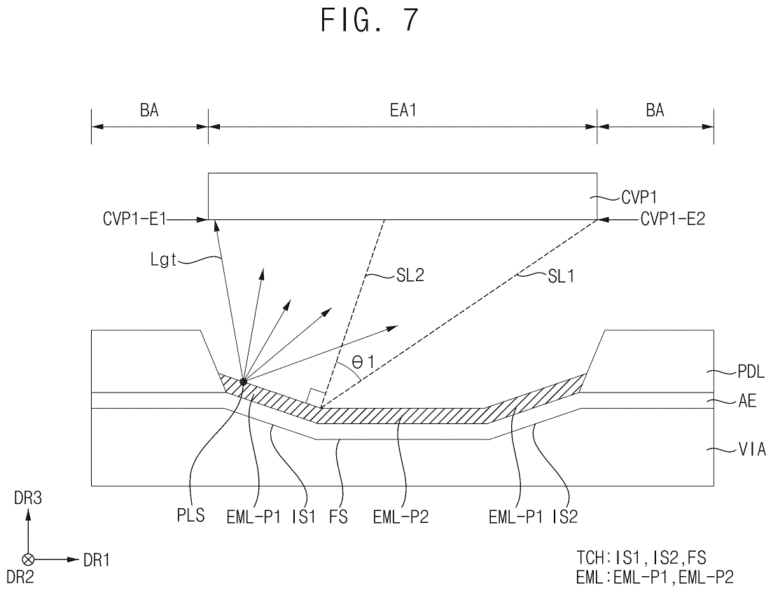

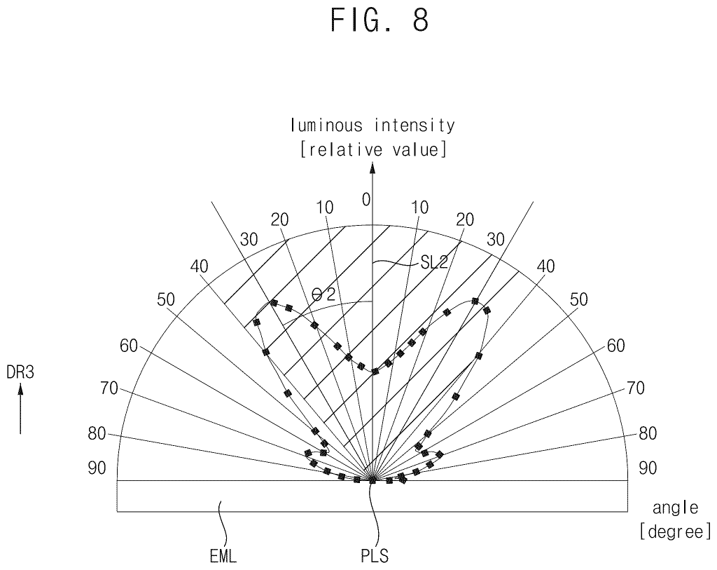

FIG. 6 is a schematic cross-sectional view illustrating a direction in which light emitted from a light emitting layer travels in the display device of FIG. 2. FIG. 7 is a schematic cross-sectional view for explaining a first angle. FIG. 8 is a view for explaining a second angle.

Referring to FIG. 6, the display device DD according to an embodiment may include the via-insulating layer VIA, the lower electrode AE, the light emitting layer EML, the pixel defining layer PDL, and the first color conversion pattern CVP1. An overlapping structure between the light emitting layer EML and the first color conversion pattern CVP1 may be substantially the same as an overlapping structure of the light emitting layer EML and the second color conversion pattern (for example, the second color conversion pattern CVP2 of FIG. 2). The overlapping structure between the light emitting layer EML and the first color conversion pattern CVP1 may be substantially the same as an overlapping structure between the light emitting layer EML and the transmission pattern (for example, the transmission pattern TRP of FIG. 2). Therefore, the following description will focus on the overlapping structure between the light emitting layer EML and the first color conversion pattern CVP1.

The via-insulating layer VIA may define the trench TCH. The trench TCH may refer to a portion in which a portion of the upper surface of the via-insulating layer VIA is recessed toward a direction opposite to the third direction DR3. The trench TCH may overlap the first light emitting area EA1.

In an embodiment, the trench TCH may have an inverted trapezoidal cross-sectional shape. In other words, the trench TCH may include the first inclined surface IS1, the second inclined surface IS2, and the flat surface FS. In cross section, the first inclined surface IS1 may be spaced apart from the second inclined surface IS2 with the flat surface FS interposed therebetween. The first inclined surface IS1 may face the second inclined surface IS2. The flat surface FS may contact each of the first inclined surface IS1 and the second inclined surface IS2.

The lower electrode AE may be disposed on the via-insulating layer VIA. The lower electrode AE may overlap the first light emitting area EA1. The lower electrode AE may be disposed along the profile of the via-insulating layer VIA. In other words, the lower electrode AE may be disposed inside the trench TCH. Accordingly, the upper surface of the lower electrode AE may include the first inclined surface, the second inclined surface, and the flat surface. In this case, the first inclined surface, the second inclined surface, and the flat surface of the lower electrode AE may be disposed parallel to the first inclined surface IS1, the second inclined surface IS2, and the flat surface FS of the trench TCH, respectively.

The pixel defining layer PDL may be disposed on the via-insulating layer VIA and the lower electrode AE in the light blocking area BA. The opening (for example, the opening OP of FIG. 2) that exposes the trench TCH may be defined in the pixel defining layer PDL. In an embodiment, the pixel defining layer PDL may overlap at least a portion of the trench TCH in a plan view.

The light emitting layer EML may be disposed on the lower electrode AE. The light emitting layer EML may overlap the first light emitting area EA1. The light emitting layer EML may be disposed along the profile of the lower electrode AE. Accordingly, the light emitting layer EML may include the first portion EML-P1 disposed parallel to each of the first and second inclined surfaces of the lower electrode AE and the second portion EML-P2 disposed parallel to the flat surface of the lower electrode AE. The first portion EML-P1 of the light emitting layer EML may be disposed parallel to each of the first and second inclined surfaces IS1 and IS2 of the trench TCH. The second portion EML-P2 of the light emitting layer EML may be disposed parallel to the flat surface FS of the trench TCH.

The first color conversion pattern CVP1 may be disposed on the light emitting layer EML. The first color conversion pattern CVP1 may overlap the light emitting layer EML in the first light emitting area EA1. The first color conversion pattern CVP1 may convert the light emitted from the light emitting layer EML into a first color light (for example, red light).

The point light source PLS included in the light emitting layer EML may emit lights. In FIG. 6, the light emitted from the point light source PLS is represented by an arrow. A length of the arrow may correspond to the luminous intensity of the light.

The upper surface of the light emitting layer EML may include an inclined surface in an area adjacent to the pixel defining layer PDL (for example, an edge of the light emitting layer EML). As an example, the light emitting layer EML may include the first portion EML-P1 disposed parallel to each of the first and second inclined surfaces IS1 and IS2 of the trench TCH in the area adjacent to the pixel defining layer PDL. Accordingly, a light Lgt having the greatest luminous intensity among the lights emitted from the point light source PLS positioned in the area adjacent to the pixel defining layer PDL may be incident on the first color conversion pattern CVP1. As a result, the light conversion efficiency of the first color conversion pattern CVP1 included in the display device DD according to an embodiment may increase.

Referring further to FIGS. 7 and 8, a first imaginary straight line SL1 connecting a point where the first portion EML-P1 and the second portion EML-P2 meet and an edge of the first color conversion pattern CVP1 and forming an obtuse angle with the first portion EML-P1 may be defined. In other words, the first imaginary straight line SL1 may be defined as an imaginary straight line connecting the point where the first portion EML-P1 and the second portion EML-P2 meet and an edge of the first color conversion pattern CVP1 which has a relatively large separation distance from the first portion EML-P1.

As an example, the first color conversion pattern CVP1 may include a first edge CVP1-E1 overlapping the first inclined surface IS1 of the trench TCH and a second edge CVP1-E2 overlapping the second inclined surface IS2 of the trench TCH. For example, the first imaginary straight line SL1 may be defined as an imaginary straight line connecting a point where the first portion EML-P1 adjacent to the first inclined surface IS1 and the second portion EML-P2 meet and the second edge CVP1-E2.

A second imaginary straight line SL2 extending perpendicular to the first portion EML-P1 of the light emitting layer EML may be defined. Here, an angle formed by the first imaginary straight line SL1 and the second imaginary straight line SL2 may be defined as a first angle θ1.

As illustrated in FIG. 8, the point light source PLS included in the light emitting layer EML may emit lights at various angles. A horizontal axis may correspond to the surface of the light emitting layer EML in cross-section, and a vertical axis may correspond to a straight line perpendicular to the light emitting layer EML (for example, the second imaginary straight line SL2) in cross-section. The vertical axis may correspond to the luminous intensity of the light emitted from the light emitting layer EML.

In this case, an angle formed between a travel direction of the light Lgt having the greatest luminous intensity among the lights emitted from the point light source PLS and the second imaginary straight line SL2 may be defined as a second angle θ2.

In an embodiment, the first angle θ1 may be greater than the second angle θ2. For example, the second angle θ2 may have a value in a range of about 30 degrees to about 40 degrees, and the first angle θ1 may have a value in a range of about 40 degrees to about 60 degrees. Accordingly, among the lights emitted from the point light source PLS, lights with relatively large luminous intensity (for example, a hatched area of FIG. 8) may be incident on the first color conversion pattern CVP1. As a result, the light conversion efficiency of the first color conversion pattern CVP1 included in the display device DD may be further increased.

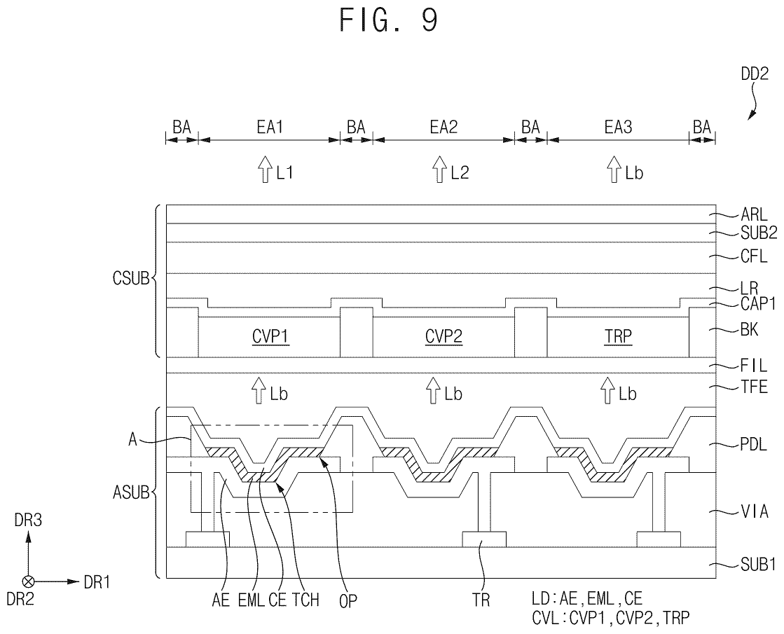

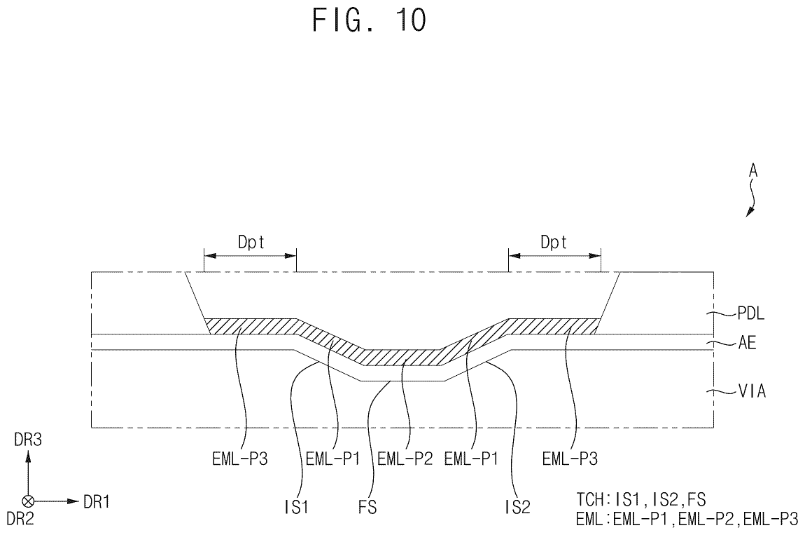

FIG. 9 is a schematic cross-sectional view illustrating a display device according to an embodiment. FIG. 10 is an enlarged schematic cross-sectional view of area ‘A’ of FIG. 9.

Referring to FIGS. 9 and 10, a display device DD2 according to an embodiment may include an array substrate ASUB, a color conversion substrate CSUB, and a filling layer FIL disposed between the array substrate ASUB and the color conversion substrate CSUB. The array substrate ASUB may include a first substrate SUB1, a driving element TR, an insulating structure, a via-insulating layer VIA, a light emitting element LD, a pixel defining layer PDL, and an encapsulation layer TFE. In this case, the light emitting element LD may include a lower electrode AE, a light emitting layer EML, and an upper electrode CE. The color conversion substrate CSUB may include an anti-reflection layer ARL, a second substrate SUB2, a color filter layer CFL, a low refractive layer LR, a first capping layer CAP1, a bank layer BK, a color conversion layer. CVL, and a second capping layer. In this case, the color conversion layer CVL may include a first color conversion pattern CVP1, a second color conversion pattern CVP2, and a transmission pattern TRP.

The display device DD2 may be substantially the same as the display device DD described with reference to FIG. 2, except that the pixel defining layer PDL is spaced apart from a trench TCH defined by the via-insulating layer VIA in a plan view. Hereinafter, descriptions overlapping descriptions of the display device DD described with reference to FIG. 2 may be omitted or simplified.

The via-insulating layer VIA may be disposed on the first substrate SUB1. The via-insulating layer VIA may define the trench TCH. The trench TCH may overlap each of first to third light emitting areas EA1, EA2, and EA3.

In an embodiment, the trench TCH may have an inverted trapezoidal cross-sectional shape. In other words, the trench TCH may include a first inclined surface IS1, a second inclined surface IS2, and a flat surface FS.

The lower electrode AE may be disposed on the via-insulating layer VIA. The lower electrode AE may overlap each of the first to third light emitting areas EA1, EA2, and EA3. The lower electrode AE may extend into an interior of the trench TCH on the via-insulating layer VIA. In other words, the lower electrode AE may be disposed along the profile of the via-insulating layer VIA.

Accordingly, an upper surface of the lower electrode AE may include a first inclined surface, a second inclined surface, a first flat surface, a second flat surface, and a third flat surface. In cross section, the first inclined surface may be spaced apart from the second inclined surface with the first flat surface interposed therebetween. The first inclined surface may face the second inclined surface. The second flat surface may extend from the first inclined surface and may partially overlap the pixel defining layer PDL. The third flat surface may extend from the second inclined surface and may partially overlap the pixel defining layer PDL.

The pixel defining layer PDL may be disposed on the via-insulating layer VIA and the lower electrode AE in the light blocking area BA. An opening OP exposing the trench TCH may be defined in the pixel defining layer PDL. The pixel defining layer PDL may cover an edge of the lower electrode AE and expose the upper surface of the lower electrode AE.

In an embodiment, as illustrated in FIG. 10, the pixel defining layer PDL may be spaced apart from the trench TCH by a selectable distance in a plan view. For example, in consideration of alignment errors that occur during the manufacturing process of the display device DD2, the pixel defining layer PDL may be spaced apart from the trench TCH by a selectable distance in a plan view. Accordingly, defects caused by the alignment errors that occur during the manufacturing process may be suppressed.

In an embodiment, a separation distance Dpt in a plan view between the pixel defining layer PDL and the trench TCH may be about 6.6 micrometers or less. For example, the separation distance Dpt in a plan view may be about 2 micrometers. In case that the separation distance Dpt in a plan view exceeds about 6.6 micrometers, the light conversion efficiency of the display device DD2 may be lower than that of the display device according to a comparative example (for example, the display device DD′ of FIG. 5).

The light emitting layer EML may be disposed on the via-insulating layer VIA. As an example, the light emitting layer EML may be disposed on the lower electrode AE. The light emitting layer EML may overlap each of the first to third light emitting areas EA1, EA2, and EA3. The light emitting layer EML may be disposed along the profile of the lower electrode AE. Accordingly, the light emitting layer EML may include a first portion EML-P1 disposed parallel to each of the first and second inclined surfaces of the lower electrode AE and a second portion EML-P2 disposed parallel to the first flat surface of the lower electrode AE. For example, the first portion EML-P1 of the light emitting layer EML may be disposed parallel to each of the first and second inclined surfaces IS1 and IS2 of the trench TCH. The second portion EML-P2 of the light emitting layer EML may be disposed parallel to the flat surface FS of the trench TCH.

In an embodiment, the light emitting layer EML may further include a third portion EML-P3 extending from the first portion EML-P1 and disposed on the via-insulating layer VIA. As an example, the third portion EML-P3 of the light emitting layer EML may be disposed on the lower electrode AE, may extend from the first portion EML-P1, and may contact the pixel defining layer PDL. The third portion EML-P3 of the light emitting layer EML may have a flat upper surface. In other words, the third portion EML-P3 of the light emitting layer EML may be disposed parallel to each of the second and third flat surfaces of the lower electrode AE.

Hereinafter, the effects of the disclosure will be described with reference to FIGS. 5, 7, and 10 again.

The light conversion efficiency according to the first angle θ1 was measured in display devices satisfying the Comparative example, Example 1, Example 2, Example 3, Example 4, Example 5, Example 6, Example 7, Example 8, and Example 9. The first angle θ1 is formed between the first imaginary straight line SL1, which connects a point where the first portion EML-P1 and the second portion EML-P2 meet and an edge of the first color conversion pattern CVP1 and forms an obtuse angle with the first portion EML-P1, and the second imaginary straight line SL2, which extends perpendicular to the first portion EML-P1. The second angle θ2 is formed between a travel direction of a light having the greatest luminous intensity among lights emitted from the first portion EML-P1 and the second imaginary straight line SL2.

The number of pixels per unit area (or, pixels per inch, PPI) of each of the display devices is 220, and the second angle θ2 of the light emitting layer included in each of the pixels is about 30 degrees.

The display devices satisfying Examples 1, 2, and 3 (for example, the display device DD of FIG. 7) may include the via-insulating layer VIA in which the trench TCH is defined, the lower electrode disposed along the profile of the via-insulating layer VIA, and the light emitting layer EML disposed along the profile of the lower electrode AE. Accordingly, the first portion EML-P1 of the light emitting layer EML is disposed parallel to the first inclined surface IS1 of the trench TCH. The second portion EML-P2 of the light emitting layer EML is disposed parallel to the flat surface FS of the trench TCH. A separation distance Dpt in a plan view between the pixel defining layer PDL and the trench TCH is about 0 micrometer. The first angle θ1 of the display device satisfying the Example 1 is about 53.4 degrees. The first angle θ1 of the display device satisfying the Example 2 is about 57.4 degrees. The first angle θ1 of the display device satisfying the Example 3 is about 58.1 degrees.

The display devices satisfying Example 4, 5, and 6 (for example, the display device DD2 of FIG. 10) may include the via-insulating layer VIA in which the trench TCH is defined, the lower electrode disposed along the profile of the via-insulating layer VIA, and the light emitting layer EML disposed along the profile of the lower electrode AE. Accordingly, the first portion EML-P1 of the light emitting layer EML is disposed parallel to the first inclined surface IS1 of the trench TCH. The second portion EML-P2 of the light emitting layer EML is disposed parallel to the flat surface FS of the trench TCH. A separation distance Dpt in a plan view between the pixel defining layer PDL and the trench TCH is about 2 micrometers. The first angle θ1 of the display device satisfying the Example 4 is about 52.2 degrees. The first angle θ1 of the display device satisfying the Example 5 is about 56.0 degrees. The first angle θ1 of the display device satisfying the Example 6 is about 56.5 degrees.

The display devices satisfying Example 7, 8, and 9 (for example, the display device DD2 of FIG. 10) may include the via-insulating layer VIA in which the trench TCH is defined, the lower electrode disposed along the profile of the via-insulating layer VIA, and the light emitting layer EML disposed along the profile of the lower electrode AE. Accordingly, the first portion EML-P1 of the light emitting layer EML is disposed parallel to the first inclined surface IS1 of the trench TCH. The second portion EML-P2 of the light emitting layer EML is disposed parallel to the flat surface FS of the trench TCH. A separation distance Dpt in a plan view between the pixel defining layer PDL and the trench TCH is about 6.6 micrometers. The first angle θ1 of the display device satisfying the Example 7 is about 50.8 degrees. The first angle θ1 of the display device satisfying the Example 8 is about 51.8 degrees. The first angle θ1 of the display device satisfying the Example 9 is about 52.3 degrees.

The display device satisfying Comparative example (for example, the display device DD′ of FIG. 5) may include the via-insulating layer VIA′, the lower electrode AE′ disposed on the via-insulating layer VIA′, and the light emitting layer EML′ disposed on the lower electrode AE′. Each of the via insulating layer VIA′, the lower electrode AE′, and the light emitting layer EML′ has a flat upper surface.

As a result, Referring to Table 1 below, based on the light conversion efficiency of the display device satisfying the Comparative example, the light conversion efficiency of the display device satisfying the Example 1 was measured to be about 104.0%, the light conversion efficiency of the display device satisfying the Example 2 was measured to be about 104.4%, and the light conversion efficiency of the display device satisfying the Example 3 was measured to be about 103.9%.

Based on the light conversion efficiency of the display device satisfying the Comparative example, the light conversion efficiency of the display device satisfying the Example 4 was measured to be about 103.4%, the light conversion efficiency of the display device satisfying the Example 5 was measured to be about 103.6%, and the light conversion efficiency of the display device satisfying the Example 6 was measured to be about 103.2%.

Based on the light conversion efficiency of the display device satisfying the Comparative example, the light conversion efficiency of the display device satisfying the Example 7 was measured to be about 101.0%, the light conversion efficiency of the display device satisfying the Example 8 was measured to be about 101.1%, and the light conversion efficiency of the display device satisfying the Example 9 was measured to be about 101.1%.

TABLE 1

| | first | separation d | light conversion |
|---|---|---|---|
| | angle | istance | efficiency |
| | (degree) | (micrometer) | (%) |
| Comparative | — | — | 100 |
| example | | | |
| Example 1 | 53.4 | 0 | 104.0 |
| Example 2 | 57.4 | 0 | 104.4 |
| Example 3 | 58.1 | | 103.9 |
| Example 4 | 52.2 | 2 | 103.4 |
| Example 5 | 56.0 | | 103.6 |
| Example 6 | 56.5 | | 103.2 |
| Example 7 | 50.8 | 6.6 | 101.0 |
| Example 8 | 51.8 | | 101.1 |
| Example 9 | 52.3 | | 101.1 |

From these results, it can be seen that the light conversion efficiency of the display device DD is increased by including the light emitting layer EML, which may include the first portion EML-P1 disposed parallel to the first inclined surface IS1 of the trench TCH and the second portion EML-P2 disposed parallel to the flat surface FS of the trench TCH, and by making the first angle θ1 is larger than the second angle θ2.

The display device DD2 according to an embodiment may include the pixel defining layer PDL spaced apart from the trench TCH by a selectable distance Dpt in a plan view in consideration of the alignment errors that occur during the manufacturing process. However, it can be seen that in case that the separation distance Dpt increases, the light conversion efficiency of the display device DD2 decreases.

The disclosure can be applied to various display devices. For example, the disclosure is applicable to various display devices such as display devices for vehicles, ships and aircraft, portable communication devices, display devices for exhibition or information transmission, medical display devices, and the like within the spirit and the scope of the disclosure.

The foregoing is illustrative of embodiments of the disclosure, and is not to be construed as limiting thereof. Although a few embodiments have been described with reference to the figures, those skilled in the art will readily appreciate that many variations and modifications may be made therein without departing from the spirit and scope of the disclosure and as defined in the appended claims.

What is claimed is:

1. A display device comprising:
a first substrate including a light emitting area;
a via-insulating layer disposed on the first substrate, the via-insulating layer defining a trench including a substantially inclined surface and a substantially flat surface, the trench overlapping the light emitting area;
a light emitting layer disposed on the via-insulating layer in the light emitting area, the light emitting layer including a first portion disposed parallel to the substantially inclined surface and a second portion disposed parallel to the substantially flat surface; and
a color conversion layer disposed on the light emitting layer and overlapping the light emitting area,
wherein a first angle formed between a first imaginary straight line, which connects a point where the first portion and the second portion of the light emitting layer meet and an edge of the color conversion layer and forms an obtuse angle with the first portion, and a second imaginary straight line, which extends perpendicular to the first portion, is greater than a second angle formed between a travel direction of a light having a greatest luminous intensity among lights emitted from the first portion and the second imaginary straight line.

2. The display device of claim 1, wherein light having the greatest luminous intensity among the lights emitted from the light emitting layer is incident on the color conversion layer.

3. The display device of claim 1, wherein the trench has a substantially inverted trapezoid cross-sectional shape.

4. The display device of claim 1, further comprising:
a lower electrode disposed between the via-insulating layer and the light emitting layer,
wherein the lower electrode extends into an interior of the trench on the via-insulating layer.

5. The display device of claim 4, wherein the lower electrode includes:
a substantially inclined surface disposed parallel to the substantially inclined surface of the trench; and
a substantially flat surface disposed parallel to the substantially flat surface of the trench.

6. The display device of claim 5, wherein the light emitting layer is disposed along a profile of the lower electrode.

7. The display device of claim 1, wherein
the light emitting area includes a first light emitting area, a second light emitting area, and a third light emitting area;
the trench overlaps each of the first light emitting area, the second light emitting area, and the third light emitting area;
the light emitting layer overlaps each of the first light emitting area, the second light emitting area, and the third light emitting area; and
the color conversion layer includes a first color conversion pattern overlapping the light emitting layer in the first light emitting area, a second color conversion pattern overlapping the light emitting layer in the second light emitting area, and a transmission pattern overlapping the light emitting layer in the third light emitting area.

8. The display device of claim 4, further comprising:
a pixel defining layer disposed on the via-insulating layer and defining an opening exposing the trench.

9. The display device of claim 8, wherein the pixel defining layer overlaps at least a portion of the trench in a plan view.

10. The display device of claim 1, further comprising:
a second substrate disposed on the color conversion layer; and
a filling layer disposed between the first substrate and the second substrate.

11. A display device comprising:
a first substrate including a light emitting area;
a via-insulating layer disposed on the first substrate, the via-insulating layer defining a trench including a substantially inclined surface and a substantially flat surface, the trench overlapping the light emitting area;
a light emitting layer disposed on the via-insulating layer in the light emitting area, the light emitting layer including a first portion disposed parallel to the substantially inclined surface and a second portion disposed parallel to the substantially flat surface;
a pixel defining layer disposed on the via-insulating layer, defining an opening exposing the trench, and spaced apart from the trench by a selectable distance in a plan view; and
a color conversion layer disposed on the light emitting layer and overlapping the light emitting area,
wherein a first angle formed between a first imaginary straight line, which connects a point where the first portion and the second portion of the light emitting layer meet and an edge of the color conversion layer and forms an obtuse angle with the first portion, and a second imaginary straight line, which extends perpendicular to the first portion, is greater than a second angle formed between a travel direction of a light having a greatest luminous intensity among lights emitted from the first portion and the second imaginary straight line.

12. The display device of claim 11, wherein a separation distance between the pixel defining layer and the trench is about 6.6 micrometers or less in the plan view.

13. The display device of claim 11, wherein the light emitting layer further includes:
a third portion disposed on the via-insulating layer, extending from the first portion, and contacting the pixel defining layer.

14. The display device of claim 11, wherein light having the greatest luminous intensity among the lights emitted from the light emitting layer is incident on the color conversion layer.

15. The display device of claim 11, wherein the trench has a substantially inverted trapezoid cross-sectional shape.

16. The display device of claim 11, further comprising:
a lower electrode disposed between the via-insulating layer and the light emitting layer, wherein the lower electrode extends into an interior of the trench on the via-insulating layer.

17. The display device of claim 16, wherein the lower electrode includes:
a substantially inclined surface disposed parallel to the substantially inclined surface of the trench; and
a substantially flat surface disposed parallel to the substantially flat surface of the trench.

18. The display device of claim 17, wherein the light emitting layer is disposed along a profile of the lower electrode.

19. The display device of claim 11, wherein
the light emitting area includes a first light emitting area, a second light emitting area, and a third light emitting area,
the trench overlaps each of the first light emitting area, the second light emitting area, and the third light emitting area,
the light emitting layer overlaps each of the first light emitting area, the second light emitting area, and the third light emitting area, and
the color conversion layer includes a first color conversion pattern overlapping the light emitting layer in the first light emitting area, a second color conversion pattern overlapping the light emitting layer in the second light emitting area, and a transmission pattern overlapping the light emitting layer in the third light emitting area.

20. The display device of claim 11, further comprising:
a second substrate disposed on the color conversion layer, and
a filling layer disposed between the first substrate and the second substrate.
